(19) United States
(12) Patent Application Publication
(10) Pub. No.: US 2024/0049573 A1
(43) Pub. Date: Feb. 8, 2024

(54) DISPLAY DEVICE

(71) Applicant: Samsung Display Co., LTD., Yongin-si (KR)

(72) Inventors: JONGHYUN PARK, Yongin-si (KR); SOOK-HWAN BAN, Yongin-si (KR); JUNGHYUK CHO, Yongin-si (KR); HYO-JUN KIM, Yongin-si (KR); JAE-BANG YU, Yongin-si (KR); DEOKCHAN YOON, Yongin-si (KR); JAESUNG LEE, Yongin-si (KR); DONGUK CHOI, Yongin-si (KR)

(21) Appl. No.: 18/141,034

(22) Filed: Apr. 28, 2023

(30) Foreign Application Priority Data
Aug. 8, 2022 (KR) 10-2022-0098765

(51) Int. Cl. H10K 59/80

(52) U.S. Cl. CPC H10K 59/8731; H10K 59/879; H10K 59/1201

(57) ABSTRACT

A display device includes: a light emitting element; a first inorganic encapsulation layer disposed on the light emitting element to cover the light emitting element, and including a first encapsulation layer, a plasma treatment layer disposed on the first encapsulation layer, and a second encapsulation layer disposed on the plasma treatment layer; an organic encapsulation layer disposed on the first inorganic encapsulation layer; and a second inorganic encapsulation layer disposed on the organic encapsulation layer.

This application claims priority to Korean Patent Application No. 10-2022-0098765, filed on Aug. 8, 2022, and all the benefits accruing therefrom under 35 U.S.C. § 119, the content of which in its entirety is herein incorporated by reference.

### BACKGROUND

### 1. Field

Embodiments of the present disclosure relate to a display device.

### 2. Description of the Related Art

A display device may include a light emitting element and an encapsulation layer. The encapsulation layer may protect the light emitting element from external moisture and oxygen by sealing the light emitting element.

The encapsulation layer may include a first inorganic encapsulation layer, an organic encapsulation layer, and a second inorganic encapsulation layer, which are sequentially stacked. In this case, when a thickness of the first inorganic encapsulation layer and/or a thickness of the second inorganic encapsulation layer included in the encapsulation layer is reduced in order to reduce a thickness of the display device, a sealing property of the encapsulation layer (e.g., capability to protect the light emitting element from external moisture and oxygen) may deteriorate.

### SUMMARY

An aspect of the present disclosure is to provide a display device including an encapsulation layer having a relatively small thickness and an improved sealing property.

However, aspects of the present disclosure are not limited to the above-described aspect, and may be variously changed without departing from the idea and scope of the present disclosure.

To achieve the above-described aspect of the present disclosure, according to one embodiment of the present disclosure, there is provided a display device including: a light emitting element; a first inorganic encapsulation layer disposed on the light emitting element to cover the light emitting element, and including a first encapsulation layer, a plasma treatment layer disposed on the first encapsulation layer, and a second encapsulation layer disposed on the plasma treatment layer; an organic encapsulation layer disposed on the first inorganic encapsulation layer; and a second inorganic encapsulation layer disposed on the organic encapsulation layer.

According to one embodiment, the plasma treatment layer may include hydrogen-plasma-treated silicon oxynitride.

According to one embodiment, a thickness of the plasma treatment layer may be greater than or equal to about 10 angstroms, and less than or equal to about 50 angstroms.

According to one embodiment, a difference between a refractive index of the plasma treatment layer and a refractive index of the first encapsulation layer that is adjacent to the plasma treatment layer may be less than or equal to about 0.05, and a difference between the refractive index of the plasma treatment layer and a refractive index of the second encapsulation layer that is adjacent to the plasma treatment layer may be less than or equal to about 0.05.

According to one embodiment, a thickness of the first inorganic encapsulation layer may be greater than or equal to about 3500 angstroms, and less than or equal to about 4500 angstroms.

According to one embodiment, each of the first encapsulation layer and the second encapsulation layer may include silicon oxynitride.

According to one embodiment, the second encapsulation layer may include: a high-oxygen region making direct contact with a bottom surface of the organic encapsulation layer; and a low-oxygen region located under the high-oxygen region, and an average oxygen content per unit volume of the second encapsulation layer in the high-oxygen region may be greater than an average oxygen content per unit volume of the second encapsulation layer in the low-oxygen region.

According to one embodiment, a difference between a refractive index of the second encapsulation layer in the high-oxygen region making direct contact with the organic encapsulation layer and a refractive index of the organic encapsulation layer may be less than or equal to about 0.05.

According to one embodiment, an oxygen content per unit volume of the second encapsulation layer may gradually increase in a direction from the low-oxygen region toward the high-oxygen region, and a refractive index of the second encapsulation layer may gradually decrease in the direction from the low-oxygen region toward the high-oxygen region.

According to one embodiment, a thickness of the high-oxygen region may be greater than or equal to about 500 angstroms, and less than or equal to about 700 angstroms.

According to one embodiment, a thickness of the low-oxygen region may be greater than or equal to about 500 angstroms.

According to one embodiment, the first encapsulation layer may include: a first buffer region; and a first encapsulation region located over the first buffer region, and an average oxygen content per unit volume of the first encapsulation layer in the first buffer region may be greater than an average oxygen content per unit volume of the first encapsulation layer in the first encapsulation region.

According to one embodiment, a difference between an average refractive index of the first encapsulation layer in the first buffer region and an average refractive index of the first encapsulation layer in the first encapsulation region may be less than or equal to about 0.05.

According to one embodiment, a thickness of the first buffer region may be greater than or equal to about 300 angstroms, and less than or equal to about 500 angstroms.

According to one embodiment, the second inorganic encapsulation layer may include silicon oxynitride.

According to one embodiment, a thickness of the second inorganic encapsulation layer may be greater than or equal to about 7000 angstroms, and less than or equal to about 10000 angstroms.

According to one embodiment, the second inorganic encapsulation layer may include: a second buffer region making direct contact with a top surface of the organic encapsulation layer; and a second encapsulation region disposed over the second buffer region, and an average oxygen content per unit volume of the second inorganic encapsulation layer in the second buffer region may be greater than an average oxygen content per unit volume of the second inorganic encapsulation layer in the second encapsulation region.

According to one embodiment, a difference between an average refractive index of the second inorganic encapsulation layer in the second buffer region and an average refractive index of the second inorganic encapsulation layer in the second encapsulation region may be less than or equal to about 0.05.

According to one embodiment, a thickness of the second buffer region may be greater than or equal to about 300 angstroms, and less than or equal to about 500 angstroms.

To achieve the above-described aspect of the present disclosure, according to one embodiment of the present disclosure, there is provided a display device including: a light emitting element; a first encapsulation layer disposed on the light emitting element to cover the light emitting element, and including a first encapsulation layer, a first plasma treatment layer disposed on the first encapsulation layer, and a second encapsulation layer disposed on the first plasma treatment layer; an organic encapsulation layer disposed on the first inorganic encapsulation layer; and a second inorganic encapsulation layer disposed on the organic encapsulation layer, and including a third encapsulation layer, a second plasma treatment layer disposed on the third encapsulation layer, and a fourth encapsulation layer disposed on the second plasma treatment layer.

According to one embodiment, a thickness of the first inorganic encapsulation layer may be greater than or equal to about 3500 angstroms, and less than or equal to about 4500 angstroms, and a thickness of the second inorganic encapsulation layer may be greater than or equal to about 3000 angstroms, and less than or equal to about 3800 angstroms.

According to one embodiment, a thickness of the fourth encapsulation layer may be greater than or equal to about 500 angstroms.

According to one embodiment, each of the first plasma treatment layer and the second plasma treatment layer may include hydrogen-plasma-treated silicon oxynitride.

According to one embodiment, each of thicknesses of the first plasma treatment layer and the second plasma treatment layer may be greater than or equal to about 10 angstroms, and less than or equal to about 50 angstroms.

According to one embodiment, a difference between a refractive index of the second plasma treatment layer and a refractive index of the third encapsulation layer that is adjacent to the second plasma treatment layer may be less than or equal to about 0.05, and a difference between the refractive index of the second plasma treatment layer and a refractive index of the fourth encapsulation layer that is adjacent to the second plasma treatment layer may be less than or equal to about 0.05.

According to one embodiment, each of the first encapsulation layer, the second encapsulation layer, the third encapsulation layer, and the fourth encapsulation layer may include silicon oxynitride.

According to one embodiment, the first encapsulation layer may include: a first buffer region; and a first encapsulation region located over the first buffer region, and an average oxygen content per unit volume of the first encapsulation layer in the first buffer region may be greater than an average oxygen content per unit volume of the first encapsulation layer in the first encapsulation region.

According to one embodiment, the third encapsulation layer may include: a second buffer region making direct contact with a top surface of the organic encapsulation layer; and a second encapsulation region disposed over the second buffer region, and an average oxygen content per unit volume of the third encapsulation layer in the second buffer region may be greater than an average oxygen content per unit volume of the third encapsulation layer in the second encapsulation region.

According to one embodiment, a difference between an average refractive index of the third encapsulation layer in the second buffer region and an average refractive index of the third encapsulation layer in the second encapsulation region may be less than or equal to about 0.05.

According to one embodiment, a thickness of the second buffer region may be greater than or equal to about 300 angstroms, and less than or equal to about 500 angstroms.

According to embodiments of the present disclosure, the display device may include: a first inorganic encapsulation layer including a first encapsulation layer, a plasma treatment layer disposed on the first encapsulation layer, and a second encapsulation layer disposed on the plasma treatment layer; an organic encapsulation layer disposed on the first inorganic encapsulation layer; and a second inorganic encapsulation layer disposed on the organic encapsulation layer.

Since the first inorganic encapsulation layer includes the plasma treatment layer, even when the first inorganic encapsulation layer has a relatively small thickness, the first inorganic encapsulation layer can have a relatively excellent sealing property.

In addition, since the second encapsulation layer is disposed on the plasma treatment layer, even when a surface of the plasma treatment layer is exposed to moisture so as to have a stain, the stain can be prevented from being visually recognized by a user of the display device.

However, effects of the present disclosure are not limited to the above-described effects, and may be variously expanded without departing from the idea and scope of the present disclosure.

### BRIEF DESCRIPTION OF THE DRAWINGS

FIG. 1 is a plan view for describing a display device according to one embodiment of the present disclosure.

FIG. 2 is a sectional view for describing the display device of FIG. 1.

FIGS. 3 and 4 are views for describing an encapsulation layer included in the display device of FIG. 1.

FIGS. 5 and 6 are views for describing a method for manufacturing the encapsulation layer of FIG. 3.

FIG. 7 is a sectional view for describing an encapsulation layer according to another embodiment of the present disclosure.

FIG. 8 is a flow chart for describing a method for manufacturing the encapsulation layer of FIG. 7.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present. Furthermore, relative terms, such as “lower,” “under” or “bottom” and “upper,” “over” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. Hereinafter, a display device according to embodiments of the present disclosure will be described in more detail with reference to the accompanying drawings. The same or similar reference numerals will be used for the same elements in the accompanying drawings.

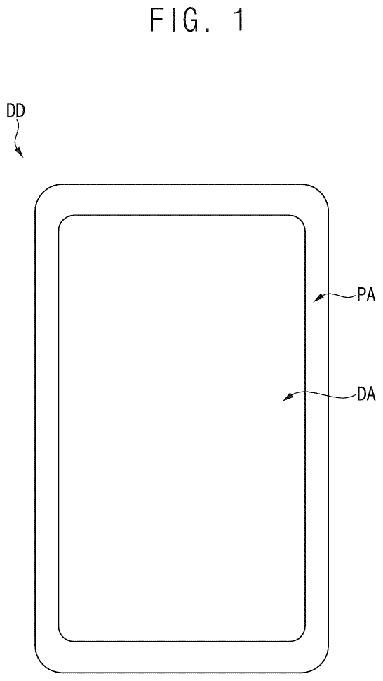

FIG. 1 is a plan view for describing a display device according to one embodiment of the present disclosure.

Referring to FIG. 1, a display device DD may be partitioned into a display area DA and a peripheral area PA.

The display area DA may be an area for displaying an image. To this end, a plurality of pixels may be disposed in the display area DA. Each of the pixels may be a minimum unit for emitting a light. The pixels may be disposed over the whole display area DA. For example, the pixels may be arranged in the display area DA in a matrix shape, a diamond shape, a stripe shape, or the like.

The peripheral area PA may be located on at least one side of the display area DA. For example, as shown in FIG. 1, the peripheral area PA may surround the display area DA. Drivers (e.g., a gate driver and/or a data driver) may be disposed in the peripheral area PA, and an electronic element such as an integrated circuit, a printed circuit board, and the like may be electrically connected to the peripheral area PA.

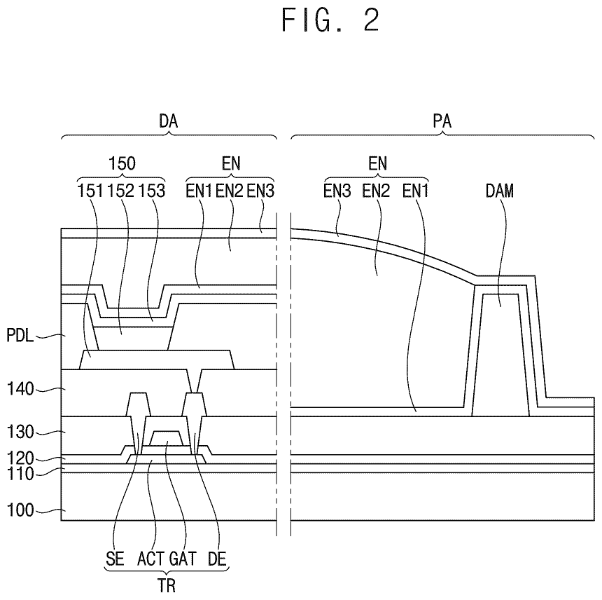

FIG. 2 is a sectional view for describing the display device of FIG. 1. FIG. 2 may be a sectional view showing a portion of each of the display area DA and the peripheral area PA of the display device DD.

Referring to FIG. 2, the display device DD may include a base substrate 100, a buffer layer 110, a transistor TR, a gate insulating layer 120, an interlayer-insulating layer 130, a via-insulating layer 140, a light emitting element 150, a pixel defining layer PDL, an encapsulation layer EN, and a dam DAM. The transistor TR and the light emitting element 150 may be disposed in the display area DA, the transistor TR may include an active layer ACT, a gate electrode GAT, a source electrode SE, and a drain electrode DE, and the light emitting element 150 may include a first electrode 151, a light emitting layer 152, and a second electrode 153. The dam DAM may be disposed in the peripheral area PA.

The base substrate 100 may include glass, quartz, plastic, and the like. According to one embodiment, the base substrate 100 may have a flexible, bendable, or rollable characteristic.

The buffer layer 110 may be disposed on the base substrate 100. The buffer layer 110 may include an inorganic insulating material. For example, the buffer layer 110 may include silicon oxide, silicon nitride, silicon oxynitride, and the like. The buffer layer 110 may serve to block impurities diffused from the base substrate 100 so that the active layer ACT of the transistor TR may not be damaged by the impurities. In addition, the buffer layer 110 may control a heat provision rate during a crystallization process for forming the active layer ACT, so that the active layer ACT may be formed relatively uniformly.

The active layer ACT may be disposed on the buffer layer 110. According to one embodiment, the active layer ACT may include a silicon semiconductor material. For example, the active layer ACT may include amorphous silicon, polycrystalline silicon, and the like. According to another embodiment, the active layer ACT may include an oxide semiconductor material. For example, the active layer ACT may include zinc oxide, zinc-tin oxide, zinc-indium oxide, indium oxide, titanium oxide, indium-gallium-zinc oxide, indium-zinc-tin oxide, and the like.

The gate insulating layer 120 may be disposed on the active layer ACT. The gate insulating layer 120 may include an inorganic insulating material. For example, the gate insulating layer 120 may include silicon oxide, silicon nitride, silicon oxynitride, titanium oxide, tantalum oxide, and the like. The gate insulating layer 120 may serve to electrically insulate the active layer ACT and the gate electrode GAT from each other.

The gate electrode GAT may be disposed on the gate insulating layer 120. The gate electrode GAT may include a conductive material. For example, the gate electrode GAT may include a metal, an alloy, conductive metal oxide, a transparent conductive material, and the like. A gate signal for turning on/off the transistor TR by adjusting electrical conductivity of the active layer ACT may be applied to the gate electrode GAT.

The interlayer-insulating layer 130 may be disposed on the gate electrode GAT. The interlayer-insulating layer 130 may include an organic insulating material and/or an inorganic insulating material. The interlayer-insulating layer 130 may serve to electrically insulate the source electrode SE and the drain electrode DE from the gate electrode GAT.

The source electrode SE and the drain electrode DE may be disposed on the interlayer-insulating layer 130. Each of the source electrode SE and the drain electrode DE may include a conductive material. For example, each of the source electrode SE and the drain electrode DE may include a metal, an alloy, conductive metal oxide, a transparent conductive material, and the like. Each of the source electrode SE and the drain electrode DE may make electrical contact with the active layer ACT through a contact hole formed through the interlayer-insulating layer 130 and the gate insulating layer 120.

The via-insulating layer 140 may be disposed on the source electrode SE and the drain electrode DE. The via-insulating layer 140 may include an organic insulating material. For example, the via-insulating layer 140 may include a polyacryl-based resin, a polyimide-based resin, an acryl-based resin, and the like. Accordingly, a top surface of the via-insulating layer 140 may be substantially flat.

The first electrode 151 may be disposed on the via-insulating layer 140. The first electrode 151 may include a conductive material. For example, the first electrode 151 may include a metal, an alloy, conductive metal oxide, a transparent conductive material, and the like. The first electrode 151 may make electrical contact with the source electrode SE or the drain electrode DE through a contact hole formed through the via-insulating layer 140. According to one embodiment, the first electrode 151 may be referred to as an anode electrode.

The pixel defining layer PDL may be disposed on the first electrode 151. The pixel defining layer PDL may include an organic insulating material. For example, the pixel defining layer PDL may include a polyacryl-based compound, a polyimide-based compound, and the like. The pixel defining layer PDL may partition light emission regions of the pixels. To this end, the pixel defining layer PDL may define a pixel opening exposing the first electrode 151.

The light emitting layer 152 may be disposed on the first electrode 151 within the pixel opening. The light emitting layer 152 may include an organic light emitting material. According to one embodiment, the light emitting layer 152 may be provided as multiple layers including various functional layers. For example, the light emitting layer 152 may further include at least one of a hole injection layer, a hole transport layer, an electron transport layer, and an electron injection layer.

The second electrode 153 may be disposed on the light emitting layer 152, and may cover the pixel defining layer PDL. According to one embodiment, the second electrode 153 may be referred to as a cathode electrode.

The encapsulation layer EN may be disposed on the second electrode 153. The encapsulation layer EN may block moisture and oxygen introduced from an outside. The encapsulation layer EN may include at least one inorganic encapsulation layer and at least one organic encapsulation layer. For example, the encapsulation layer EN may include a first inorganic encapsulation layer EN1, an organic encapsulation layer EN2 disposed on the first inorganic encapsulation layer EN1, and a second inorganic encapsulation layer EN3 disposed on the organic encapsulation layer EN2.

In order to effectively block the moisture and the oxygen introduced from the outside, the encapsulation layer EN is desirable to ensure a sufficient sealing property. In addition, in order to prevent cracks being generated by stress, the encapsulation layer EN is desirable to ensure sufficient mechanical strength. Additionally, since the encapsulation layer EN is disposed on the light emitting element 150, in order to effectively transmit a light emitted from the light emitting element 150, the encapsulation layer EN is desirable to ensure a sufficient light transmittance.

A defect density may be an index for determining a sealing property. The defect density may mean a degree of defects in the first and second inorganic encapsulation layers EN1 and EN3. When the first and second inorganic encapsulation layers EN1 and EN3 have relatively high defect densities, defects formed in the first and second inorganic encapsulation layers EN1 and EN3 may react with the moisture and oxygen atoms introduced from the outside to oxidize the first and second inorganic encapsulation layers EN1 and EN3, so that display quality of the display device may deteriorate. Therefore, in order to improve a sealing property of the encapsulation layer EN, the first and second inorganic encapsulation layers EN1 and EN3 are desirable to have relatively low defect densities.

A stress intensity factor may be an index for determining mechanical strength. In detail, the stress intensity factor may correspond to energy required to generate cracks in the first and second inorganic encapsulation layers EN1 and EN3. In this case, as the stress intensity factor increases, the energy required to generate the cracks in the first and second inorganic encapsulation layers EN1 and EN3 may be increased. In other words, in order to improve mechanical strength of the encapsulation layer EN, the first and second inorganic encapsulation layers EN1 and EN3 are desirable to have a relatively large stress intensity factor.

A refractive index may be an index for determining a light transmittance. As refractive indexes of the first and second inorganic encapsulation layers EN1 and EN3 decrease, refraction of a light passing through the first and second inorganic encapsulation layers EN1 and EN3 may be decreased. Accordingly, a change in a path of the light passing through the first and second inorganic encapsulation layers EN1 and EN3 may be small, so that a light transmittance may be improved.

Meanwhile, according to one embodiment, each of the first and second inorganic encapsulation layers EN1 and EN3 may include silicon oxynitride. While the silicon oxynitride has a relatively high light transmittance, the silicon oxynitride may have a relatively low sealing property and relatively low mechanical strength.

For example, when compared with silicon nitride, which may be used as a material for an inorganic encapsulation layer, a defect density of the silicon nitride may be lower than a defect density of the silicon oxynitride. In other words, the silicon oxynitride may have a lower sealing property than the silicon nitride.

In addition, a stress intensity factor of the silicon nitride may be greater than a stress intensity factor of the silicon oxynitride. For example, the stress intensity factor of the silicon nitride may be about 1.68 MPa, and the stress intensity factor of the silicon oxynitride may be about 1.31 MPa to about 1.43 MPa depending on a nitrogen content of the silicon oxynitride. In other words, the silicon oxynitride may have lower mechanical strength than the silicon nitride.

However, the silicon oxynitride may have an excellent light transmittance as compared with the silicon nitride. For example, a refractive index of the silicon nitride may be greater than about 1.8, and a refractive index of the silicon oxynitride may be about 1.4 to about 1.8 depending on an oxygen content per unit volume of the silicon oxynitride.

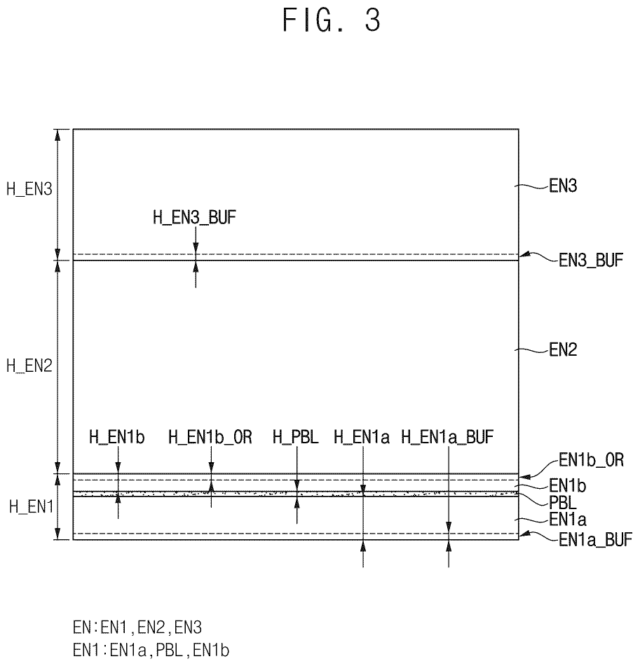

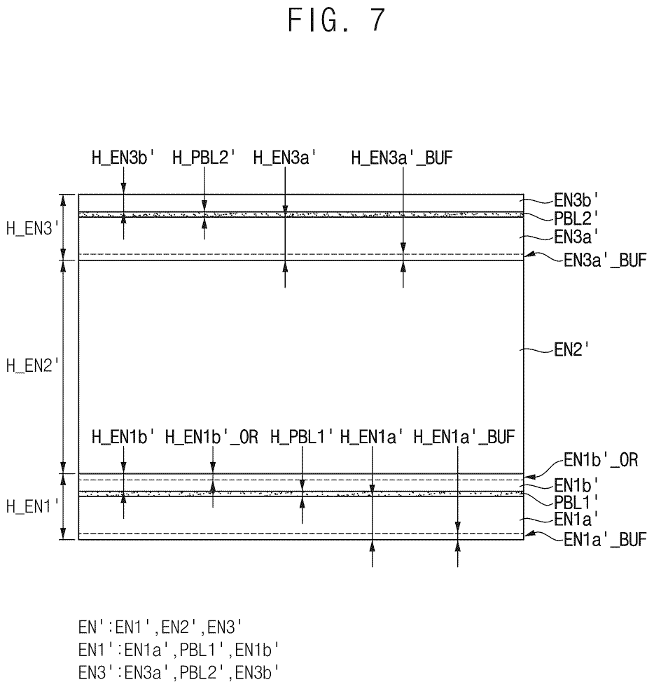

According to the present disclosure, each of the first and second inorganic encapsulation layers EN1 and EN3 may include silicon oxynitride. Accordingly, a light transmittance of the encapsulation layer EN may be improved. At the same time, in order to improve the sealing property and the mechanical strength of the encapsulation layer EN, the encapsulation layer EN may include a plasma treatment layer (e.g., PBL of FIG. 3). This will be described below in detail with reference to FIGS. 3 and 7.

The dam DAM may be disposed in the peripheral area PA. The dam DAM may include a material included in the pixel defining layer PDL and/or a material included in the via-insulating layer 140. The dam DAM may serve to block the organic encapsulation layer EN2. Accordingly, in a region of the dam DAM and outside the dam DAM of the peripheral area PA, the first inorganic encapsulation layer EN1 and the second inorganic encapsulation layer EN3 may make direct contact with each other.

Hereinafter, for convenience of description, only the encapsulation layer EN disposed in the display area DA will be described.

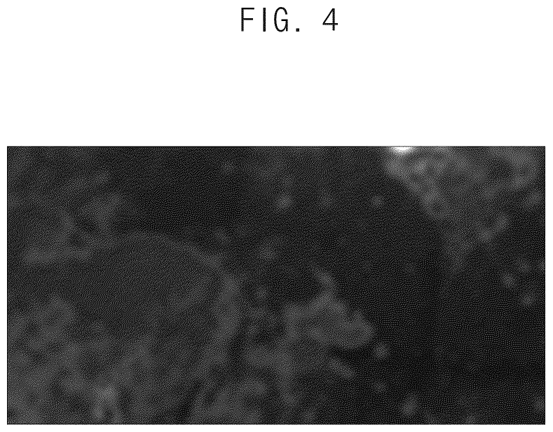

FIGS. 3 and 4 are views for describing an encapsulation layer included in the display device of FIG. 1.

Referring to FIG. 3, the encapsulation layer EN may include a first inorganic encapsulation layer EN1, an organic encapsulation layer EN2 disposed on the first inorganic encapsulation layer EN1, and a second inorganic encapsulation layer EN3 disposed on the organic encapsulation layer EN2.

The first inorganic encapsulation layer EN1 may include a first encapsulation layer EN1a, a plasma treatment layer PBL disposed on the first encapsulation layer EN1a, and a second encapsulation layer EN1b disposed on the plasma treatment layer PBL.

The first encapsulation layer EN1a may include silicon oxynitride. In this case, according to one embodiment, the first encapsulation layer EN1a may include a first buffer region EN1a_BUF. The first buffer region EN1a_BUF may be a region extending in a direction from a bottom surface of the first encapsulation layer EN1a toward a top surface of the first encapsulation layer EN1a. The first buffer region EN1a_BUF may start from the bottom surface of the first encapsulation layer EN1a and have a thickness less than a thickness of the first encapsulation layer EN1a. In this case, a region of the first encapsulation layer EN1a except for the first buffer region EN1a_BUF may be referred to as a first encapsulation region.

The first buffer region EN1a_BUF may be a region formed by setting a power of chemical vapor deposition (“CVD”) to be relatively low in order to prevent components (e.g., the light emitting layer 152) disposed under the first encapsulation layer EN1a from being damaged when the first encapsulation layer EN1a is formed by a CVD scheme.

In this case, in order to prevent the components disposed under the first encapsulation layer EN1a from being damaged, the first buffer region EN1a_BUF is desirable to have a sufficient thickness H_EN1a_BUF. For example, a thickness H_EN1a_BUF of the first buffer region EN1a_BUF may be greater than or equal to about 300 angstroms, and less than or equal to about 500 angstroms. As used herein, a thickness of a layer is a distance from a bottom surface of the layer to a top surface of the layer.

Since the power of the CVD is set to be relatively low, in the first buffer region EN1a_BUF, the first encapsulation layer EN1a may include a relatively large amount of oxygen. For example, an average oxygen content per unit volume of the first encapsulation layer EN1a in the first buffer region EN1a_BUF may be greater than an average oxygen content per unit volume of the first encapsulation layer EN1a in the first encapsulation region. Accordingly, a refractive index of the first encapsulation layer EN1a in the first buffer region EN1a_BUF may be smaller than a refractive index of the first encapsulation layer EN1a in the first encapsulation region.

In this case, a difference between the refractive index of the first encapsulation layer EN1a in the first buffer region EN1a_BUF and the refractive index of the first encapsulation layer EN1a in the first encapsulation region may be less than or equal to about 0.05 (i.e., relatively small). For example, the refractive index of the first encapsulation layer EN1a in the first buffer region EN1a_BUF may be about 1.62, and the refractive index of the first encapsulation layer EN1a in the first encapsulation region may be about 1.64. Accordingly, the light emitted from the light emitting element 150 may not be substantially reflected (or refracted) at an interface between the first buffer region EN1a_BUF and the first encapsulation region, so that the light transmittance of the encapsulation layer EN may be improved.

The plasma treatment layer PBL may include silicon oxynitride subjected to a hydrogen plasma treatment. When the silicon oxynitride is subjected to the hydrogen plasma treatment, a number of dangling bonds of the silicon oxynitride may be reduced. In other words, free radicals or outermost electrons present in the silicon oxynitride may be combined with hydrogen, so that a defect density of the silicon oxynitride may be decreased, and a stress intensity factor of the silicon oxynitride may be increased. Accordingly, the plasma treatment layer PBL may serve to improve a sealing property and mechanical strength of the first inorganic encapsulation layer EN1.

In addition, a difference between a refractive index of the plasma treatment layer PBL and a refractive index of the first encapsulation layer EN1a that is adjacent to the plasma treatment layer PBL may be less than or equal to about 0.05. For example, the refractive index of the plasma treatment layer PBL may be about 1.66, and the refractive index of the first encapsulation layer EN1a in the first encapsulation region may be about 1.64. Accordingly, the light emitted from the light emitting element 150 may not be substantially reflected (or refracted) at an interface between the plasma treatment layer PBL and the first encapsulation layer EN1a, so that the light transmittance of the encapsulation layer EN may be improved.

Similarly, a difference between the refractive index of the plasma treatment layer PBL and a refractive index of the second encapsulation layer EN1b that is adjacent to the plasma treatment layer PBL may be less than or equal to about 0.05. Accordingly, the light emitted from the light emitting element 150 may not be substantially reflected (or refracted) at an interface between the plasma treatment layer PBL and the second encapsulation layer EN1b, so that the light transmittance of the encapsulation layer EN may be improved.

According to one embodiment, a thickness H_PBL of the plasma treatment layer PBL may be greater than or equal to about 10 angstroms, and less than or equal to about 50 angstroms. When the thickness H_PBL of the plasma treatment layer PBL is less than about angstroms, the sealing property and the mechanical strength of the first inorganic encapsulation layer EN1 may not be sufficiently ensured. In addition, when the thickness H_PBL of the plasma treatment layer PBL is greater than about 50 angstroms, a light transmittance of the light emitted from the light emitting element 150 may be decreased.

The second encapsulation layer EN1b may include silicon oxynitride. When a surface of the plasma treatment layer PBL is exposed to moisture, a stain (see FIG. 4) may occur on the plasma treatment layer PBL. Since the second encapsulation layer EN1b is disposed on the plasma treatment layer PBL, the stain may be prevented from being visually recognized by a user of the display device DD.

Unlike the above configuration, when assuming that the second encapsulation layer EN1b is not disposed on the plasma treatment layer PBL, the plasma treatment layer PBL may make direct contact with the organic encapsulation layer EN2. In this case, when the surface of the plasma treatment layer PBL is exposed to the moisture to allow the stain to occur on the plasma treatment layer PBL, the stain may be visually recognized by the user of the display device DD.

According to one embodiment, the second encapsulation layer EN1b may include a high-oxygen region EN1b_OR making direct contact with a bottom surface of the organic encapsulation layer EN2. The high-oxygen region EN1b_OR may be a region extending in a direction from a top surface of the second encapsulation layer EN1b toward a bottom surface of the second encapsulation layer EN1b. The high-oxygen region EN1b_OR may start from the top surface of the second encapsulation layer EN1b and have a thickness less than a thickness of the second encapsulation layer EN1b. In this case, a region of the second encapsulation layer EN1b except for the high-oxygen region EN1b_OR may be referred to as a low-oxygen region.

The high-oxygen region EN1b_OR may be formed by adjusting a proportion of oxygen to be relatively large in a process of forming the second encapsulation layer EN1b. Accordingly, in the high-oxygen region EN1b_OR, the second encapsulation layer EN1b may have a relatively high oxygen content. For example, an average oxygen content per unit volume of the second encapsulation layer EN1b in the high-oxygen region EN1b_OR may be greater than an average oxygen content per unit volume of the second encapsulation layer EN1b in the low-oxygen region.

Since the second encapsulation layer EN1b has the relatively high oxygen content in the high-oxygen region EN1b_OR, the organic encapsulation layer EN2 may be relatively uniformly disposed on the second encapsulation layer EN1b. In more detail, energy of an interface between the high-oxygen region EN1b_OR having a relatively high oxygen content and the organic encapsulation layer EN2 may be relatively low. Accordingly, when the organic encapsulation layer EN2 is applied onto the high-oxygen region EN1b_OR, the organic encapsulation layer EN2 may be spread relatively easily on the high-oxygen region EN1b_OR, so that uniformity of the organic encapsulation layer EN2 may be improved. To this end, the high-oxygen region EN1b_OR is desirable to have a sufficient thickness H_EN1b_OR. For example, a thickness H_EN1b_OR of the high-oxygen region EN1b_OR may be greater than or equal to about 500 angstroms, and less than or equal to about 700 angstroms.

Since the second encapsulation layer EN1b has the relatively high oxygen content in the high-oxygen region EN1b_OR, an average refractive index of the second encapsulation layer EN1b in the high-oxygen region EN1b_OR may be smaller than an average refractive index of the second encapsulation layer EN1b in the low-oxygen region. For example, the average refractive index of the second encapsulation layer EN1b in the high-oxygen region EN1b_OR may be about 1.5, and the average refractive index of the second encapsulation layer EN1b in the low-oxygen region may be about 1.64.

In this case, according to one embodiment, a difference between a refractive index of the second encapsulation layer EN1b in the high-oxygen region EN1b_OR that is adjacent to the organic encapsulation layer EN2 and a refractive index of the organic encapsulation layer EN2 that is adjacent to the high-oxygen region EN1b_OR may be less than or equal to 0.05. Preferably, the refractive index of the second encapsulation layer EN1b in the high-oxygen region EN1b_OR that is adjacent to the organic encapsulation layer EN2 may be substantially equal to the refractive index of the organic encapsulation layer EN2 that is adjacent to the high-oxygen region EN1b_OR. For example, each of the refractive index of the second encapsulation layer EN1b in the high-oxygen region EN1b_OR that is adjacent to the organic encapsulation layer EN2 and the refractive index of the organic encapsulation layer EN2 that is adjacent to the high-oxygen region EN1b_OR may be about 1.5. Accordingly, the light emitted from the light emitting element 150 may not be substantially reflected (or refracted) at an interface between the second encapsulation layer EN1b and the organic encapsulation layer EN2, so that the light transmittance of the encapsulation layer EN may be improved.

According to one embodiment, an oxygen content per unit volume of the second encapsulation layer EN1b may gradually increase in a direction from the low-oxygen region toward the high-oxygen region EN1b_OR. Accordingly, the refractive index of the second encapsulation layer EN1b may gradually decrease in the direction from the low-oxygen region toward the high-oxygen region EN1b_OR. Since the refractive index is not rapidly changed within the second encapsulation layer EN1b as described above, the light emitted from the light emitting element 150 and passing through the second encapsulation layer EN1b may not be substantially reflected (or refracted), so that the light transmittance of the encapsulation layer EN may be improved.

According to one embodiment, in order to prevent the stain (see FIG. 4) from being visually recognized, the low-oxygen region is desirable to have a sufficient thickness. For example, a thickness of the low-oxygen region may be greater than or equal to about 500 angstroms. When the thickness of the low-oxygen region is less than about 500 angstroms, the stain formed on the plasma treatment layer PBL may be visually recognized by the user of the display device DD. In this case, the thickness of the low-oxygen region may be defined as a value obtained by subtracting the thickness H_EN1b_OR of the high-oxygen region EN1b_OR from a thickness H_EN1b of the second encapsulation layer EN1b.

Since the first inorganic encapsulation layer EN1 includes the plasma treatment layer PBL, even when the first inorganic encapsulation layer EN1 has a relatively small thickness H_EN1, the first inorganic encapsulation layer EN1 may have an excellent sealing property and excellent mechanical strength. For example, a thickness H_EN1 of the first inorganic encapsulation layer EN1 may be greater than or equal to about 3500 angstroms, and less than about 4500 angstroms. At the same time, the first inorganic encapsulation layer EN1 may include silicon oxynitride, so that the first inorganic encapsulation layer EN1 may have an excellent light transmittance. In this case, the thickness H_EN1 of the first inorganic encapsulation layer EN1 may be defined as a sum of a thickness H_EN1a of the first encapsulation layer EN1a, the thickness H_PBL of the plasma treatment layer PBL, and the thickness H_EN1b of the second encapsulation layer EN1b.

The organic encapsulation layer EN2 may be disposed on the first inorganic encapsulation layer EN1. The organic encapsulation layer EN2 may include an organic insulating material. In this case, a top surface of the organic encapsulation layer EN2 may be relatively flat. According to one embodiment, a thickness H_EN2 of the organic encapsulation layer EN2 may be about 30000 angstroms.

The second inorganic encapsulation layer EN3 may be disposed on the organic encapsulation layer EN2. The second inorganic encapsulation layer EN3 may include silicon oxynitride.

According to one embodiment, the second inorganic encapsulation layer EN3 may include a second buffer region EN3_BUF making direct contact with the top surface of the organic encapsulation layer EN2. The second buffer region EN3_BUF may be a region extending in a direction from a bottom surface of the second inorganic encapsulation layer EN3 toward a top surface of the second inorganic encapsulation layer EN3. The second buffer region EN3_BUF may start from the bottom surface of the second inorganic encapsulation layer EN3 and have a thickness less than a thickness of the second inorganic encapsulation layer EN3. In this case, a region of the second inorganic encapsulation layer EN3 except for the second buffer region EN3_BUF may be referred to as a second encapsulation region.

The second buffer region EN3_BUF may be a region formed by setting a power of the CVD to be relatively low in order to prevent components (e.g., the organic encapsulation layer EN2) disposed under the second inorganic encapsulation layer EN3 from being damaged when the second inorganic encapsulation layer EN3 is formed by the CVD scheme.

In this case, in order to prevent the components disposed under the second inorganic encapsulation layer EN3 from being damaged, the second buffer region EN3_BUF is desirable to have a sufficient thickness H_EN3_BUF. For example, a thickness H_EN3_BUF of the second buffer region EN3_BUF may be greater than or equal to about 300 angstroms, and less than or equal to about 500 angstroms.

Since the power of the CVD is set to be relatively low, in the second buffer region EN3_BUF, the second inorganic encapsulation layer EN3 may include a relatively large amount of oxygen. For example, an average oxygen content per unit volume of the second inorganic encapsulation layer EN3 in the second buffer region EN3_BUF may be greater than an average oxygen content per unit volume of the second inorganic encapsulation layer EN3 in the second encapsulation region. Accordingly, a refractive index of the second inorganic encapsulation layer EN3 in the second buffer region EN3_BUF may be smaller than a refractive index of the second inorganic encapsulation layer EN3 in the second encapsulation region.

In this case, a difference between the refractive index of the second inorganic encapsulation layer EN3 in the second buffer region EN3_BUF and the refractive index of the second inorganic encapsulation layer EN3 in the second encapsulation region may be less than or equal to 0.05. For example, the refractive index of the second inorganic encapsulation layer EN3 in the second buffer region EN3_BUF may be about 1.62, and the refractive index of the second inorganic encapsulation layer EN3 in the second encapsulation region may be about 1.64. Accordingly, the light emitted from the light emitting element 150 may not be substantially reflected (or refracted) at an interface between the second buffer region EN3_BUF and the second encapsulation region, so that the light transmittance of the encapsulation layer EN may be improved.

Unlike the first inorganic encapsulation layer EN1, the second inorganic encapsulation layer EN3 may not include the plasma treatment layer PBL. Therefore, in order to ensure a sufficient sealing property and sufficient mechanical strength, a thickness H_EN3 of the second inorganic encapsulation layer EN3 is desirable to be greater than the thickness H_EN1 of the first inorganic encapsulation layer EN1.

For example, in order to satisfy a condition that less than about 40% of the total thickness H_EN3 of the second inorganic encapsulation layer EN3 is oxidized by WHTS evaluation of exposing the second inorganic encapsulation layer EN3 to a humidity of 85% at 85 degrees Celsius for 1000 hours, the thickness H_EN3 of the second inorganic encapsulation layer EN3 may be set to greater than or equal to about 7000 angstroms, and less than about 10000 angstroms.

Unlike the above configuration, the first inorganic encapsulation layer EN1 may include the plasma treatment layer PBL having an excellent sealing property, so that when WHTS evaluation of exposing the first inorganic encapsulation layer EN1 to a humidity of 85% at 85 degrees Celsius for 1000 hours is performed, the first encapsulation layer EN1a disposed under the plasma treatment layer PBL may not be substantially oxidized. Therefore, even when the first inorganic encapsulation layer EN1 has a relatively small thickness H_EN1 as compared with the second inorganic encapsulation layer EN3, the first inorganic encapsulation layer EN1 may have an excellent sealing property.

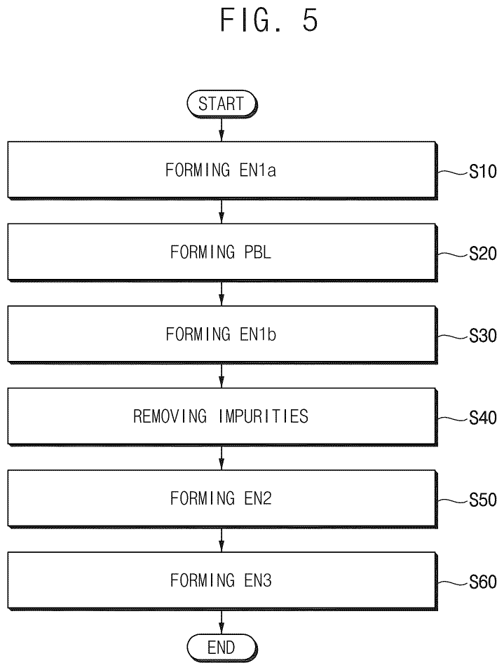

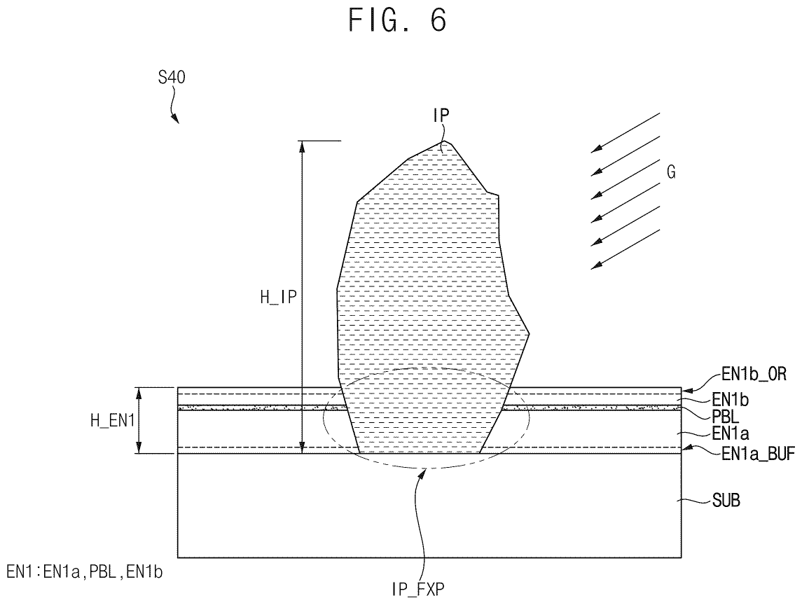

FIGS. 5 and 6 are views for describing a method for manufacturing the encapsulation layer of FIG. 3.

Referring to FIGS. 3 and 5, the encapsulation layer EN may be formed by: forming a first encapsulation layer EN1a (S10); forming a plasma treatment layer PBL on the first encapsulation layer EN1a (S20); forming a second encapsulation layer EN1b on the plasma treatment layer PBL (S30); removing a foreign substance (IP of FIG. 6) (S40); forming an organic encapsulation layer EN2 on the second encapsulation layer EN1b (S50); and forming a second inorganic encapsulation layer EN3 on the organic encapsulation layer EN2 (S60).

Referring to FIG. 6, the foreign substance IP may be disposed on the substrate SUB. The substrate SUB may include a base substrate 100, a buffer layer 110, a transistor TR, a gate insulating layer 120, an interlayer-insulating layer 130, a via-insulating layer 140, a light emitting element 150, and a pixel defining layer PDL, which have been described with reference to FIG. 2. In this case, according to one embodiment, the foreign substance IP may be disposed on a second electrode 153 included in the light emitting element 150.

The first encapsulation layer EN1a, the plasma treatment layer PBL, and the second encapsulation layer EN1b may be sequentially formed on the second electrode 153 (S10, S20, and S30). In this case, the foreign substance IP may be fixed by the first encapsulation layer EN1a, the plasma treatment layer PBL, and the second encapsulation layer EN1b. For example, the foreign substance IP may include a fixed part IP_FXP fixed by the first encapsulation layer EN1a, the plasma treatment layer PBL, and the second encapsulation layer EN1b.

When a thickness H_IP of the foreign substance IP is relatively large, cracks may be generated in the encapsulation layer EN due to the foreign substance IP. Accordingly, the sealing property and the like of the encapsulation layer EN may deteriorate.

In order to prevent the above problem, the foreign substance IP may be removed by spraying a gas G having a high pressure toward the foreign substance IP (S40). In this case, when assuming that a thickness H_EN1 of the first inorganic encapsulation layer EN1 is relatively large (e.g., the thickness H_EN1 of the first inorganic encapsulation layer EN1 is greater than or equal to about 7000 angstroms), a volume of the fixed part IP_FXP fixed by the first inorganic encapsulation layer EN1 may be relatively large, so that the foreign substance IP may not be easily removed by the gas G. In other words, in order to remove the foreign substance IP, the first inorganic encapsulation layer EN1 is desirable to have a relatively small thickness H_EN1.

According to the present disclosure, the first inorganic encapsulation layer EN1 may have the relatively small thickness H_EN1. In more detail, the first inorganic encapsulation layer EN1 may have a thickness that is greater than or equal to about 3500 angstroms and less than or equal to about 4500 angstroms. Accordingly, in a process of removing the foreign substance IP (S40), the foreign substance IP may be easily removed by the gas G.

FIG. 7 is a sectional view for describing an encapsulation layer according to another embodiment of the present disclosure.

Referring to FIG. 7, according to another embodiment of the present disclosure, an encapsulation layer EN may include a first inorganic encapsulation layer EN1′, an organic encapsulation layer EN2′ disposed on the first inorganic encapsulation layer EN1′, and a second inorganic encapsulation layer EN3′ disposed on the organic encapsulation layer EN2′.

The first inorganic encapsulation layer EN1′ may include a first encapsulation layer EN1a, a first plasma treatment layer PBL1′ disposed on the first encapsulation layer EN1a′, and a second encapsulation layer EN1b′ disposed on the first plasma treatment layer PBL1′. In this case, the first encapsulation layer EN1a, the first plasma treatment layer PBL1′, and the second encapsulation layer EN1b′ may be substantially the same as the first encapsulation layer EN1a, the plasma treatment layer PBL, and the second encapsulation layer EN1b, which have been described with reference to FIGS. 2 to 6.

In addition, the organic encapsulation layer EN2′ may be substantially the same as the organic encapsulation layer EN2 that has been described with reference to FIGS. 2 to 6.

The second inorganic encapsulation layer EN3′ may include a third encapsulation layer EN3a disposed on the organic encapsulation layer EN2′, a second plasma treatment layer PBL2′ disposed on the third encapsulation layer EN3a, and a fourth encapsulation layer EN3b′ disposed on the second plasma treatment layer PBL2′.

The third encapsulation layer EN3a′ may include silicon oxynitride. In this case, according to one embodiment, the third encapsulation layer EN3a may include a second buffer region EN3a′_BUF making direct contact with a top surface of the organic encapsulation layer EN2′. The second buffer region EN3a′_BUF may be a region extending in a direction from a bottom surface of the third encapsulation layer EN3a′ toward a top surface of the third encapsulation layer EN3a′. The second buffer region EN3a′_BUF may start from the bottom surface of the third encapsulation layer EN3a′ and have a thickness less than a thickness of the third encapsulation layer EN3a′. In this case, a region of the third encapsulation layer EN3a′ except for the second buffer region EN3a′_BUF may be referred to as a second encapsulation region.

The second buffer region EN3a′_BUF may be a region formed by setting a power of the CVD to be relatively low in order to prevent components (e.g., the organic encapsulation layer EN2′) disposed under the third encapsulation layer EN3a′ from being damaged when the third encapsulation layer EN3a′ is formed by the CVD scheme.

In this case, in order to prevent the components disposed under the third encapsulation layer EN3a′ from being damaged, the second buffer region EN3a′_BUF is desirable to have a sufficient thickness H_EN3a′_BUF. For example, a thickness H_EN3a′_BUF of the second buffer region EN3a′_BUF may be greater than or equal to about 300 angstroms, and less than or equal to about 500 angstroms.

Since the power of the CVD is set to be relatively low, in the second buffer region EN3a′_BUF, the third encapsulation layer EN3a′ may include a relatively large amount of oxygen. For example, an average oxygen content per unit volume of the third encapsulation layer EN3a′ in the second buffer region EN3a′_BUF may be greater than an average oxygen content per unit volume of the third encapsulation layer EN3a′ in the second encapsulation region. Accordingly, a refractive index of the third encapsulation layer EN3a′ in the second buffer region EN3a′_BUF may be smaller than a refractive index of the third encapsulation layer EN3a′ in the second encapsulation region.

In this case, a difference between the refractive index of the third encapsulation layer EN3a′ in the second buffer region EN3a′ _BUF and the refractive index of the third encapsulation layer EN3a′ in the second encapsulation region may be less than or equal to about 0.05. For example, the refractive index of the third encapsulation layer EN3a′ in the second buffer region EN3a′_BUF may be about 1.62, and the refractive index of the third encapsulation layer EN3a′ in the second encapsulation region may be about 1.64. Accordingly, the light emitted from the light emitting element 150 may not be substantially reflected (or refracted) at an interface between the second buffer region EN3a′_BUF and the second encapsulation region, so that a light transmittance of the encapsulation layer EN may be improved.

The second plasma treatment layer PBL2′ may include silicon oxynitride subjected to a hydrogen plasma treatment. Accordingly, the second plasma treatment layer PBL2′ may serve to improve a sealing property and mechanical strength of the second inorganic encapsulation layer EN3′.

In addition, a difference between a refractive index of the second plasma treatment layer PBL2′ and a refractive index of the third encapsulation layer EN3a′ that is adjacent to the second plasma treatment layer PBL2′ may be less than or equal to about 0.05. For example, the refractive index of the second plasma treatment layer PBL2′ may be about 1.66, and the refractive index of the third encapsulation layer EN3a′ in the second encapsulation region may be about 1.64. Accordingly, the light emitted from the light emitting element 150 may not be substantially reflected (or refracted) at an interface between the second plasma treatment layer PBL2′ and the third encapsulation layer EN3a′, so that the light transmittance of the encapsulation layer EN may be improved.

Similarly, a difference between the refractive index of the second plasma treatment layer PBL2′ and a refractive index of the fourth encapsulation layer EN3b′ that is adjacent to the second plasma treatment layer PBL2′ may be less than or equal to about 0.05. Accordingly, the light emitted from the light emitting element 150 may not be substantially reflected (or refracted) at an interface between the second plasma treatment layer PBL2′ and the fourth encapsulation layer EN3b′, so that the light transmittance of the encapsulation layer EN′ may be improved.

According to one embodiment, a thickness H_PBL2′ of the second plasma treatment layer PBL2′ may be greater than or equal to about 10 angstroms, and less than or equal to about angstroms. When the thickness H_PBL2′ of the second plasma treatment layer PBL2′ is less than about 10 angstroms, a sealing property and mechanical strength of the second inorganic encapsulation layer EN3′ may not be sufficiently ensured. In addition, when the thickness H_PBL2′ of the second plasma treatment layer PBL2′ is greater than about 50 angstroms, a light transmittance of the light emitted from the light emitting element 150 may be decreased.

The fourth encapsulation layer EN3b′ may include silicon oxynitride. When a surface of the second plasma treatment layer PBL2′ is exposed to moisture, a stain (see FIG. 4) may occur on the second plasma treatment layer PBL2′. Since the fourth encapsulation layer EN3b′ is disposed on the second plasma treatment layer PBL2′, the stain may be prevented from being visually recognized by a user of the display device DD.

Unlike the above configuration, when assuming that the fourth encapsulation layer EN3b′ is not disposed on the second plasma treatment layer PBL2′, in a case where the surface of the second plasma treatment layer PBL2′ is exposed to the moisture to allow the stain to occur on the second plasma treatment layer PBL2′, the stain may be visually recognized by the user of the display device DD.

According to one embodiment, in order to prevent the stain (see FIG. 4) from being visually recognized, the fourth encapsulation layer EN3b′ is desirable to have a sufficient thickness H_EN3b′. For example, a thickness H_EN3b′ of the fourth encapsulation layer EN3b′ may be greater than or equal to about 500 angstroms. When the thickness H_EN3b′ of the fourth encapsulation layer EN3b′ is less than about 500 angstroms, the stain formed on the second plasma treatment layer PBL2′ may be visually recognized by the user of the display device DD.

Since the second inorganic encapsulation layer EN3′ includes the second plasma treatment layer PBL2′, even when the second inorganic encapsulation layer EN3′ has a relatively small thickness H_EN3′, the second inorganic encapsulation layer EN3′ may have an excellent sealing property and excellent mechanical strength. For example, a thickness H_EN3′ of the second inorganic encapsulation layer EN3′ may be greater than or equal to about 3000 angstroms, and less than about 3800 angstroms. At the same time, the second inorganic encapsulation layer EN3′ may include silicon oxynitride, so that the second inorganic encapsulation layer EN3′ may have an excellent light transmittance. In this case, the thickness H_EN3′ of the second inorganic encapsulation layer EN3′ may be defined as a sum of a thickness H_EN3a of the third encapsulation layer EN3a, the thickness H_PBL2′ of the second plasma treatment layer PBL2′, and the thickness H_EN3b′ of the fourth encapsulation layer EN3b′.

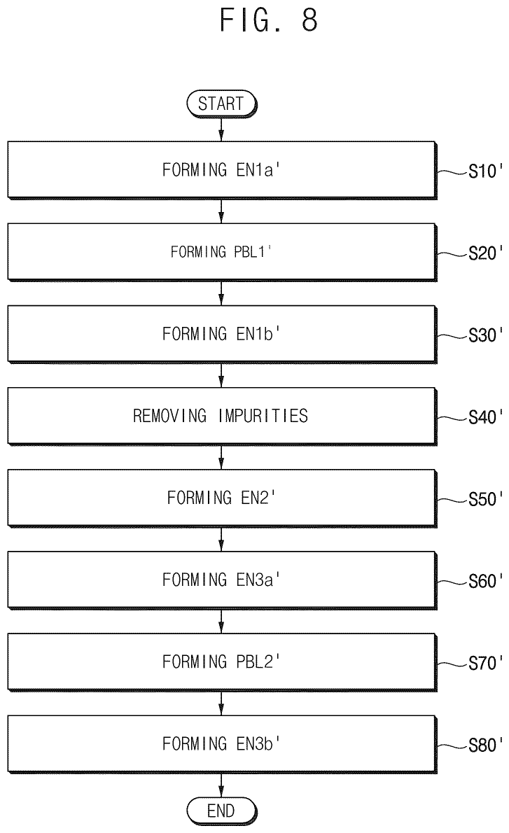

FIG. 8 is a flow chart for describing a method for manufacturing the encapsulation layer of FIG. 7.

Referring to FIGS. 7 and 8, the encapsulation layer EN′ may be formed by: forming a first encapsulation layer EN1a′ (S10′); forming a first plasma treatment layer PBL1′ on the first encapsulation layer EN1a′ (S20′); forming a second encapsulation layer EN1b′ on the first plasma treatment layer PBL1′ (S30′); removing a foreign substance (S40′); forming an organic encapsulation layer EN2′ on the second encapsulation layer EN1b′ (S50′); forming a third encapsulation layer EN3a′ on the organic encapsulation layer EN2′ (S60′); forming a second plasma treatment layer PBL2′ on the third encapsulation layer EN3a′; and forming a fourth encapsulation layer EN3b′ on the second plasma treatment layer PBL2′.

In this case, the forming of the first encapsulation layer EN1a′ (S10′), the forming of the first plasma treatment layer PBL1′ on the first encapsulation layer EN1a′ (S20′), the forming of the second encapsulation layer EN1b′ on the first plasma treatment layer PBL1′ (S30′), the removing of the foreign substance (S40′), and the forming of the organic encapsulation layer ENT on the second encapsulation layer EN1b′ (S50′) may be substantially the same as the forming of the first encapsulation layer EN1a (S10), the forming of the plasma treatment layer PBL on the first encapsulation layer EN1a (S20), the forming of the second encapsulation layer EN1b on the plasma treatment layer PBL (S30), the removing of the foreign substance (S40), and the forming of the organic encapsulation layer EN2 on the second encapsulation layer EN1b (S50), which have been described with reference to FIG. 5. For example, the removing of the foreign substance (S40′) may be substantially the same as the removing of the foreign substance IP S40 that has been described with reference to FIG. 6.

Although the embodiments of the present disclosure have been described above, it will be understood by those of ordinary skill in the art that various changes and modifications can be made to the present disclosure without departing from the idea and scope of the present disclosure as set forth in the appended claims.

The present disclosure may be applied to an electronic device having a display device. For example, the present disclosure may be applied to a smart phone, a smart watch, a tablet PC, a vehicle navigation system, a computer, a television, and the like.

What is claimed is:

1. A display device comprising:
a light emitting element;
a first inorganic encapsulation layer disposed on the light emitting element to cover the light emitting element, and including a first encapsulation layer, a plasma treatment layer disposed on the first encapsulation layer, and a second encapsulation layer disposed on the plasma treatment layer;
an organic encapsulation layer disposed on the first inorganic encapsulation layer; and
a second inorganic encapsulation layer disposed on the organic encapsulation layer.

2. The display device of claim 1, wherein the plasma treatment layer includes hydrogen-plasma-treated silicon oxynitride.

3. The display device of claim 1, wherein a thickness of the plasma treatment layer is greater than or equal to about 10 angstroms, and less than or equal to about 50 angstroms.

4. The display device of claim 1, wherein a difference between a refractive index of the plasma treatment layer and a refractive index of the first encapsulation layer that is adjacent to the plasma treatment layer is less than or equal to 0.05, and
a difference between the refractive index of the plasma treatment layer and a refractive index of the second encapsulation layer that is adjacent to the plasma treatment layer is less than or equal to 0.05.

5. The display device of claim 1, wherein a thickness of the first inorganic encapsulation layer is greater than or equal to about 3500 angstroms, and less than or equal to about 4500 angstroms.

6. The display device of claim 1, wherein each of the first encapsulation layer and the second encapsulation layer includes silicon oxynitride.

7. The display device of claim 6, wherein the second encapsulation layer includes:
a high-oxygen region making direct contact with a bottom surface of the organic encapsulation layer; and
a low-oxygen region located under the high-oxygen region, and
wherein an average oxygen content per unit volume of the second encapsulation layer in the high-oxygen region is greater than an average oxygen content per unit volume of the second encapsulation layer in the low-oxygen region.

8. The display device of claim 7, wherein a difference between a refractive index of the second encapsulation layer in the high-oxygen region making direct contact with the organic encapsulation layer and a refractive index of the organic encapsulation layer is less than or equal to 0.05.

9. The display device of claim 7, wherein an oxygen content per unit volume of the second encapsulation layer gradually increases in a direction from the low-oxygen region toward the high-oxygen region, and
a refractive index of the second encapsulation layer gradually decreases in the direction from the low-oxygen region toward the high-oxygen region.

10. The display device of claim 7, wherein a thickness of the high-oxygen region is greater than or equal to about 500 angstroms, and less than or equal to about 700 angstroms.

11. The display device of claim 7, wherein a thickness of the low-oxygen region is greater than or equal to about 500 angstroms.

12. The display device of claim 6, wherein the first encapsulation layer includes:
a first buffer region; and
a first encapsulation region located over the first buffer region, and
wherein an average oxygen content per unit volume of the first encapsulation layer in the first buffer region is greater than an average oxygen content per unit volume of the first encapsulation layer in the first encapsulation region.

13. The display device of claim 12, wherein a difference between an average refractive index of the first encapsulation layer in the first buffer region and an average refractive index of the first encapsulation layer in the first encapsulation region is less than or equal to 0.05.

14. The display device of claim 12, wherein a thickness of the first buffer region is greater than or equal to about 300 angstroms, and less than or equal to about 500 angstroms.

15. The display device of claim 1, wherein the second inorganic encapsulation layer includes silicon oxynitride.

16. The display device of claim 1, wherein a thickness of the second inorganic encapsulation layer is greater than or equal to about 7000 angstroms, and less than or equal to about 10000 angstroms.

17. The display device of claim 1, wherein the second inorganic encapsulation layer includes:
a second buffer region making direct contact with a top surface of the organic encapsulation layer; and
a second encapsulation region disposed over the second buffer region, and
wherein an average oxygen content per unit volume of the second inorganic encapsulation layer in the second buffer region is greater than an average oxygen content per unit volume of the second inorganic encapsulation layer in the second encapsulation region.

18. The display device of claim 17, wherein a difference between an average refractive index of the second inorganic encapsulation layer in the second buffer region and an average refractive index of the second inorganic encapsulation layer in the second encapsulation region is less than or equal to 0.05.

19. The display device of claim 17, wherein a thickness of the second buffer region is greater than or equal to about 300 angstroms, and less than or equal to about 500 angstroms.

20. A display device comprising:
a light emitting element;
a first encapsulation layer disposed on the light emitting element to cover the light emitting element, and including a first encapsulation layer, a first plasma treatment layer disposed on the first encapsulation layer, and a second encapsulation layer disposed on the first plasma treatment layer;
an organic encapsulation layer disposed on the first inorganic encapsulation layer; and
a second inorganic encapsulation layer disposed on the organic encapsulation layer, and including a third encapsulation layer, a second plasma treatment layer disposed on the third encapsulation layer, and a fourth encapsulation layer disposed on the second plasma treatment layer.

21. The display device of claim 20, wherein a thickness of the first inorganic encapsulation layer is greater than or equal to about 3500 angstroms, and less than or equal to about 4500 angstroms, and
a thickness of the second inorganic encapsulation layer is greater than or equal to about 3000 angstroms, and less than or equal to about 3800 angstroms.

22. The display device of claim 21, wherein a thickness of the fourth encapsulation layer is greater than or equal to about 500 angstroms.

23. The display device of claim 20, wherein each of the first plasma treatment layer and the second plasma treatment layer includes hydrogen-plasma-treated silicon oxynitride.

24. The display device of claim 20, wherein each of thicknesses of the first plasma treatment layer and the second plasma treatment layer is greater than or equal to about 10 angstroms, and less than or equal to about 50 angstroms.

25. The display device of claim 20, wherein a difference between a refractive index of the second plasma treatment layer and a refractive index of the third encapsulation layer that is adjacent to the second plasma treatment layer is less than or equal to 0.05, and
a difference between the refractive index of the second plasma treatment layer and a refractive index of the fourth encapsulation layer that is adjacent to the second plasma treatment layer is less than or equal to 0.05.

26. The display device of claim 20, wherein each of the first encapsulation layer, the second encapsulation layer, the third encapsulation layer, and the fourth encapsulation layer includes silicon oxynitride.

27. The display device of claim 26, wherein the first encapsulation layer includes:
a first buffer region; and
a first encapsulation region located over the first buffer region, and
wherein an average oxygen content per unit volume of the first encapsulation layer in the first buffer region is greater than an average oxygen content per unit volume of the first encapsulation layer in the first encapsulation region.

28. The display device of claim 26, wherein the third encapsulation layer includes:
a second buffer region making direct contact with a top surface of the organic encapsulation layer; and
a second encapsulation region disposed over the second buffer region, and
an average oxygen content per unit volume of the third encapsulation layer in the second buffer region is greater than an average oxygen content per unit volume of the third encapsulation layer in the second encapsulation region.

29. The display device of claim 28, wherein a difference between an average refractive index of the third encapsulation layer in the second buffer region and an average refractive index of the third encapsulation layer in the second encapsulation region is less than or equal to 0.05.

30. The display device of claim 28, wherein a thickness of the second buffer region is greater than or equal to about 300 angstroms, and less than or equal to about 500 angstroms.
